(19) United States
(12) Patent Application Publication
(10) Pub. No.: US 2010/0252797 A1
(43) Pub. Date: Oct. 7, 2010

(54) NONVOLATILE MEMORY DEVICE

(75) Inventor: Hiroyuki FUKUMIZU, Mie-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/725,681

(22) Filed: Mar. 17, 2010

(30) Foreign Application Priority Data
Mar. 18, 2009 (JP) 2009-065538

(51) Int. Cl. H01L 45/00

(52) U.S. Cl. 257/4; 257/E45.001

(57) ABSTRACT

A nonvolatile memory device, includes: a memory layer having a resistance changeable by performing at least one selected from applying an electric field and providing a current, the memory layer having a first major surface and a second major surface opposite to the first major surface; a plurality of first electrodes provided on the first major surface; a second electrode provided on the second major surface; a probe electrode disposed to face the plurality of first electrodes, the probe electrode having a changeable relative positional relationship with the first electrodes; and a drive unit connected to the probe electrode and the second electrode to record information in the memory layer by causing at least one selected from applying the electric field and providing the current via the probe electrode to the memory layer between the second electrode and at least one of the plurality of first electrodes.

### CROSS-REFERENCE TO RELATED APPLICATIONS

This application is based upon and claims the benefit of priority from the prior Japanese Patent Application No. 2009-065538, filed on Mar. 18, 2009; the entire contents of which are incorporated herein by reference.

### BACKGROUND

1. Field

Embodiments of the invention relate generally to a nonvolatile memory device.

2. Background Art

The NAND flash memory market has rapidly expanded due to increasing memory capacities and decreasing prices; and in recent years, NAND flash memory has encountered problems such as downsizing limitations and increasing process costs due to decreasing minimum line widths. The development of a new nonvolatile memory is expected to solve such problems.

For example, memory devices have been proposed to combine a probe array with a recording medium formed from a resistance change material having a changeable resistance.

In such a probe memory, information is recorded or read by changing the resistance by applying a voltage to the recording medium between an electrode on the back face of the recording medium and a probe electrode which may contact the top face of the recording medium. In the case where the change of the resistance in the plane parallel to the surface of the recording medium is not controlled with high precision, the separation between memory bits of information is insufficient; the density of information cannot be increased; or writing/reading errors occur.

Conversely, technology has been proposed to suppress reading errors by providing a layer of an anisotropic electrically conductive material having a high electrical conductivity in a direction perpendicular to the surface of the recording medium (for example, refer to JP-A 2007-273618 (Kokai)). However, in such a case, writing/reading errors occur when a shift occurs between the position of the memory bit of the recording medium and the position of the probe electrode.

Therefore, extremely high precision of positional control with respect to the memory bits of the recording medium is necessary for probe electrodes of conventional technology.

### SUMMARY

According to an aspect of the invention, there is provided a nonvolatile memory device, including: a memory layer having a resistance changeable by performing at least one selected from applying an electric field and providing a current, the memory layer having a first major surface and a second major surface opposite to the first major surface; a plurality of first electrodes provided on the first major surface; a second electrode provided on the second major surface; a probe electrode disposed to face the plurality of first electrodes, the probe electrode having a changeable relative positional relationship with the first electrodes; and a drive unit connected to the probe electrode and the second electrode to record information in the memory layer by causing at least the one selected from the applying the electric field and the providing the current via the probe electrode to the memory layer between the second electrode and at least one of the plurality of first electrodes.

### BRIEF DESCRIPTION OF THE DRAWINGS

FIGS. 1A and 1B are schematic views illustrating the configuration of a nonvolatile memory device according to an embodiment of the invention;

FIG. 2 is a schematic graph illustrating the characteristics of the nonvolatile memory device according to this embodiment of the invention;

FIG. 3 is a schematic perspective view illustrating the configuration of another nonvolatile memory device according to this embodiment of the invention;

FIGS. 4A and 4B are schematic cross-sectional views illustrating the configuration of another nonvolatile memory device according to this embodiment of the invention;

FIGS. 5A and 5B are schematic cross-sectional views illustrating the configuration of another nonvolatile memory device according to this embodiment of the invention;

FIGS. 6A to 6C are schematic plan views illustrating the configuration of another nonvolatile memory device according to this embodiment of the invention; and

FIG. 7 is a schematic view illustrating the configuration of another nonvolatile memory device according to this embodiment of the invention.

### DETAILED DESCRIPTION

Embodiments of the invention will now be described in detail with reference to the drawings.

In the specification of the application and the drawings, components similar to those described in regard to a drawing thereinabove are marked with like reference numerals, and a detailed description is omitted as appropriate.

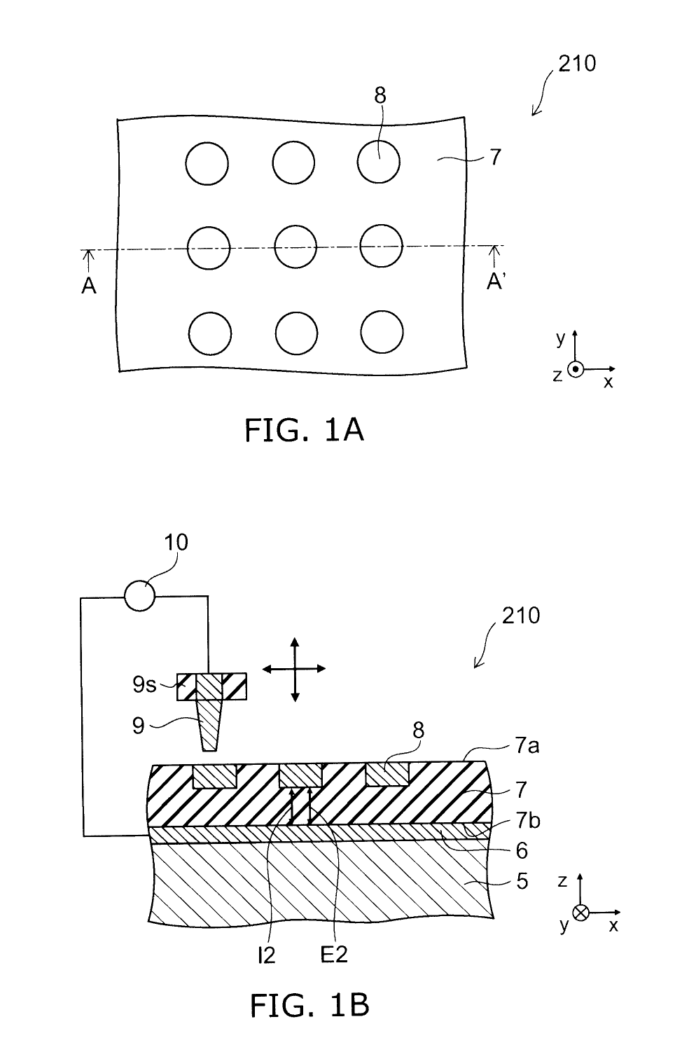

FIGS. 1A and 1B are schematic views illustrating the configuration of a nonvolatile memory device according to an embodiment of the invention.

Namely, FIG. 1A is a plan view; and FIG. 1B is a cross-sectional view along line A-A′ of FIG. 1A.

As illustrated in FIGS. 1A and 1B, a nonvolatile memory device 210 of an embodiment of the invention includes a memory layer 7 having a changeable resistance, multiple first electrodes 8 provided on a first major surface 7a of the memory layer 7, a second electrode 6 provided on a second major surface 7b on a side of the memory layer 7 opposite to the first major surface 7a, a probe electrode 9, and a drive unit 10. The probe electrode 9 and the drive unit 10 are omitted in FIG. 1A.

The second electrode 6 is provided, for example, on a substrate 5. The second electrode 6 may include, for example, tungsten, platinum, and the like. However, the invention is not limited thereto. The second electrode 6 may include any electrically conductive material. The second electrode 6 may be one continuous electrically conductive layer or, as described below, may be multiply provided on the second major surface 7b side of the memory layer 7.

The memory layer 7 may be provided on the second electrode 6. As described below, the memory layer 7 is a layer having a resistance changeable by at least one selected from applying an electric field and providing a current.

The memory layer 7 may include, for example, NiOₓ, TiOₓ, CoOₓ, TaOₓ, MnOₓ, WOₓ, Al₂O₃, FeOₓ, HfOₓ, ZnMn₂O₄, ZnFe₂O₄, ZnCO₂O₄, ZnCr₂O₄, ZnAl₂O₄, CuCoO₂, CuAlO₂, NiWO₄, NiTiO₃, CoAl₂O₄, MnAl₂O₄, ZnNiTiO₄, PrₓCa₁₋ₓMnO₃, SiC and the like.

The memory layer 7 may include ones with a dopant added to the various metal compounds recited above.

However, the invention is not limited thereto. The memory layer 7 may include any material having a resistance changeable by at least one selected from applying an electric field and providing a current. The memory layer 7 also may include a so-called phase change material which has a resistance changeable according to the change of a phase state caused by at least one selected from applying an electric field and providing a current. Thus, a material having a resistance changeable according to a phase change also is taken to be a resistance change material.

The first electrode 8 may include, for example, tungsten, platinum, and the like. However, the invention is not limited thereto. The first electrode 8 may include any electrically conductive material. Although the first electrode 8 in this specific example is buried in the memory layer 7 such that the first major surface 7a of the memory layer 7 is substantially in the same plane as the upper face of the first electrode 8, the invention is not limited thereto. The upper face of the first electrode 8 may be recessed from the first major surface 7a of the memory layer 7 or may protrude. Although the planar configuration of the first electrode 8 (the planar configuration as viewed from a direction perpendicular to the first major surface 7a) is circular, the planar configuration may have a flattened circular configuration; and various modifications described below are possible.

The probe electrode 9 is disposed to face the first electrode 8, is provided on, for example, a probe substrate 9s, and is held by the probe substrate 9s. The probe electrode 9 has a changeable relative positional relationship with the first electrode 8. The probe electrode 9 may include, for example, a probe used in an atomic force microscope. The entire probe electrode 9 may be electrically conductive, or the surface of the tip of the probe electrode 9 on the side facing the memory layer 7 may be covered with an electrically conductive thin film. The probe electrode 9 may include materials such as, for example, silicon, a carbon nanotube, and tungsten. The tip of the probe electrode 9 may be finely fabricated.

As described below, the probe electrode 9 may be multiply provided, and the number thereof is arbitrary.

The drive unit 10 is connected to the probe electrode 9 and the second electrode 6. The drive unit 10 records information in the memory layer 7 by causing at least one selected from applying an electric field E2 and providing a current I2 to the memory layer 7 between the second electrode 6 and at least one of the multiple first electrodes 8 via the multiple probe electrodes 9.

An XYZ orthogonal coordinate system will now be introduced for convenience of description in the specification of the application. In this coordinate system, one direction in a plane parallel to the first major surface 7a of the memory layer 7 is taken as an X axis direction (first direction). A direction perpendicular to the X axis direction in a plane parallel to the first major surface 7a is taken as a Y axis direction (second direction). A direction perpendicular to the X axis direction and the Y axis direction is taken as a Z axis direction (third direction). In other words, the first major surface 7a is parallel to an X-Y plane; and the first major surface 7a is perpendicular to the Z axis direction.

In this specific example, the first electrodes 8 are arranged in a matrix configuration in the X axis direction and the Y axis direction in the X-Y plane. However, the invention is not limited thereto. It is sufficient that the first electrodes 8 are multiply provided on the first major surface 7a; and the number and disposition thereof are arbitrary. Hereinbelow, the case is described where the first electrodes 8 are arranged in a matrix configuration in the X axis direction and the Y axis direction.

The probe electrode 9, for example, is movable in the X-Y plane above the memory layer 7. The probe electrode 9 can contact any of the first electrodes 8. In such a case, the probe electrode 9 also may be configured to be movable in the Z axis direction, that is, vertically above the memory layer 7 and the first electrodes 8. Thereby, the contact and non-contact between the first electrodes 8 and the probe electrode 9 can be controlled. However, a configuration may be used in which the probe electrode 9 has a fixed position in the Z axis direction to be constantly in contact with the memory layer 7 or the first electrodes 8.

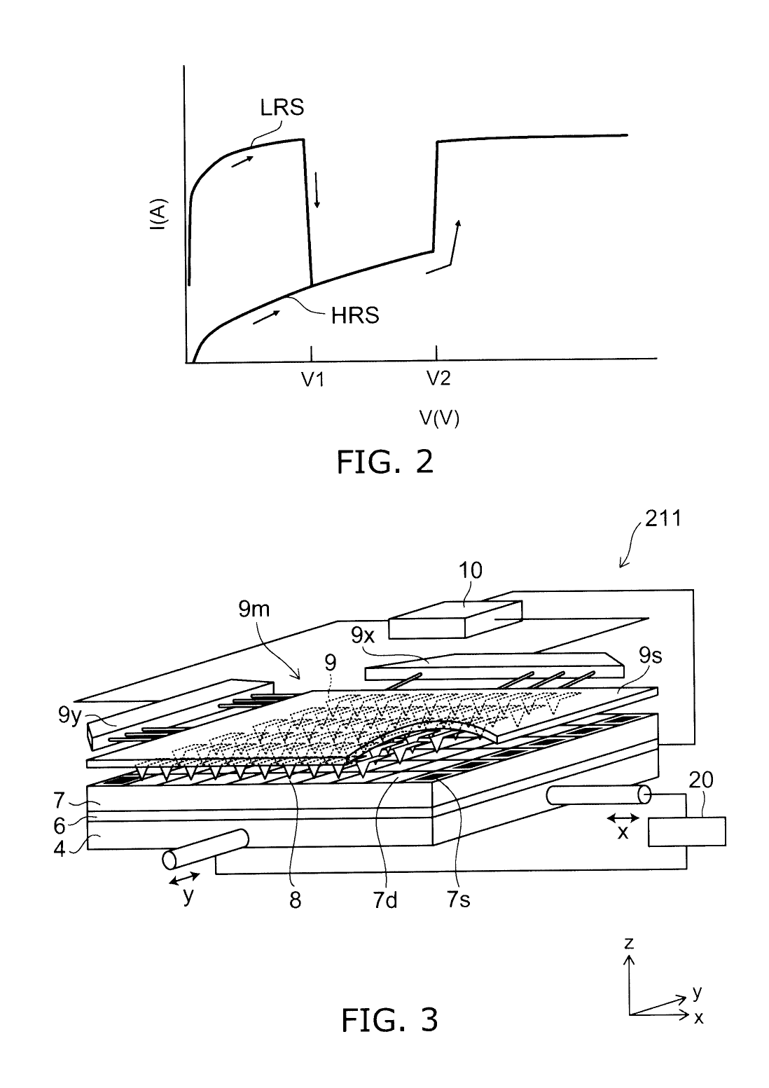

FIG. 2 is a schematic graph illustrating characteristics of the nonvolatile memory device according to an embodiment of the invention.

Namely, FIG. 2 illustrates characteristics of the memory layer 7 of the nonvolatile memory device 210. A voltage V applied to the memory layer 7 is plotted on the horizontal axis.

A current I flowing in the memory layer 7 is plotted on the vertical axis. The current I of the vertical axis is illustrated as a logarithm.

As illustrated in FIG. 2, the initial state of the memory layer 7 is taken to be a high resistance state HRS. When the voltage V applied to the memory layer 7 reaches a second transition voltage V2, the high resistance state HRS transitions to a relatively low resistance state, i.e., a low resistance state LRS.

The low resistance state LRS is maintained even when the applied voltage V is removed. As the voltage V is increased from 0 V to a first transition voltage V1, the low resistance state LRS transitions to the high resistance state HRS.

Thus, the memory layer 7 includes multiple states having different resistances. For example, data may be recorded by taking the low resistance state LRS of the memory layer 7 to be “1” and taking the high resistance state HRS to be “0.” The drive unit 10, for example, may handle the two values of “0” and “1” as data by specifying one type of a limit current flowing in the memory layer 7.

By setting two or more types of limit current values, for example, the data also can be multi-bit. In other words, although the memory layer 7 of this specific example has the two states of the high resistance state HRS and the low resistance state LRS, three or more different resistances may be used.

Although FIG. 2 illustrates characteristics in the case where a direct current voltage is applied to the memory layer 7, an extremely short pulse voltage may be applied to the memory layer 7 to operate the nonvolatile memory device 110.

In the nonvolatile memory device 210, writing may be performed by, for example, moving the probe electrode 9 in the XY plane in a raised state; lowering the probe electrode 9 to contact the first electrode 8 at a position corresponding to the desired memory bit; and writing by applying a voltage between the first electrode 8 and the second electrode 6. Thereafter, reading or erasing of the written memory bit may be performed by again moving the probe electrode 9 to the location where the writing was performed and performing reading or erasing.

The second electrode 6, the memory layer 7, and the first electrode 8 may be constructed, for example, as follows.

A Pt (platinum) film, i.e., an electrically conductive material, forming the second electrode 6 is formed on the substrate 5. A resistance change film (e.g., NiOₓ) forming the memory layer 7 is formed thereupon; and a hole pattern is made in the resistance change film by lithography and dry etching. Subsequently, an electrically conductive material of W forming the first electrode 8 is buried in the holes by, for example, CVD (Chemical Vapor Deposition) and planarized by, for example, CMP (Chemical Mechanical Polishing). Thereby, the structure illustrated in FIGS. 1A and 1B can be formed. In such a structure, the first electrodes 8 are buried in the memory layer 7.

In the nonvolatile memory device 210 having the configuration such as that recited above, the electric field E2 is applied and the current I2 is provided to the memory layer 7 by the second electrode 6 and the first electrodes 8 patterned into a prescribed configuration. To this end, it is sufficient that the probe electrode 9 contacts somewhere on the prescribed first electrode 8 corresponding to the desired memory bit; and the precision of the positional control of the probe electrode 9 is relatively mitigated.

In other words, in a probe memory of a comparative example of conventional art that does not include the first electrode 8, the probe electrode 9 contacts the first major surface 7a of the memory layer 7. Therefore, in the case where a shift of the position of the probe electrode 9 with respect to the memory layer 7 occurs, the desired memory bit is affected by another memory bit; and writing errors or reading errors easily occur.

The curvature radius of the probe electrode 9 may be reduced, for example, to increase the memory density per unit surface area. For example, the curvature radius of the probe electrode 9 may be about several tens of nm (nanometers). For the comparative example in such a case, the surface area of the memory bit of the memory layer 7 is not more than the contact surface area between the probe electrode 9 and the memory layer 7 and is extremely small. Therefore, when moving the probe electrode 9 again to the memory bit to perform reading or erasing, a high precision positional control of the probe electrode 9 is necessary. Because the probe electrode 9 contacts the memory layer 7 repeatedly, for example, the configuration and the like of the memory layer 7 change over time; it is difficult to maintain a constant contact surface area, contact position, contact resistance, and the like; and it is difficult to ensure stable operations. The configuration and the like of the probe electrode 9 also change over time; and similarly, it is difficult to ensure stable operations.

Further, because multiple memory bits are written in a short period of time, for example, the probe electrode 9 is multiply provided in an array configuration. However, in such a case, the positional control of the probe electrodes 9 requires even higher precision.

Conversely, in the nonvolatile memory device 210 according to this embodiment, the surface area of the memory bits of the memory layer 7 can be controlled at a constant size because the memory bits of the memory layer 7 are determined by the first electrodes 8. It is sufficient that each of the probe electrodes 9 is positionally aligned with respect to the first electrodes 8. Thereby, the positional alignment precision of the probe electrode 9 can be mitigated. The probe electrode 9 does not directly contact the memory layer 7; and the configuration and the like of the memory layer 7 does not change over time. Even in the case where the configuration of the probe electrode 9 changes, the surface area of the memory bits of the memory layer 7 do not change due to the first electrodes 8. Therefore, stable operations can be ensured. Moreover, even in the case where the probe electrode 9 is multiply provided in an array configuration, the positional control precision of the probe electrode 9 can be mitigated.

Thus, according to the nonvolatile memory device 210, the positional precision of the probe electrode can be mitigated to provide a probe nonvolatile memory device having reduced writing and reading defects.

For example, the surface area (the surface area in a plane parallel to the first major surface 7a) of each of the first electrodes 8 may be set to be larger than the surface area (the surface area of the tip on the side facing the first major surface 7a) of the probe electrode 9.

For example, to increase the memory density per unit surface area and realize good contact between the first electrodes 8 and the probe electrode 9, the curvature radius of the tip of the probe electrode 9 is, for example, about 15 nm. In such a case, the planar configuration of the tip of the probe electrode 9 has a diameter substantially about 15 nm. On the other hand, the diameter of the hole pattern provided in the memory layer 7 when forming the first electrodes 8 may be, for example, 50 nm. Thus, the surface area of each of the tips of the probe electrodes 9 can be smaller than the surface area of each of the first electrodes 8.

Thereby, even in the case where the position of the probe electrode 9 shifts several nanometers from the center of the first electrode 8, the first electrode 8 can be electrically connected to the probe electrode 9; the prescribed voltage can be applied to the memory bit specified by the first electrode 8; information can be recorded; and the recorded information can be read by providing the prescribed current. Thereby, high precision positional control of the stage is not necessary; and it is possible to record and read high density information.

FIG. 3 is a schematic perspective view illustrating the configuration of another nonvolatile memory device according to an embodiment of the invention.

In another nonvolatile memory device 211 according to this embodiment, a stacked unit of the second electrode 6, the memory layer 7, and the first electrodes 8 is disposed on an XY scanner 4 as illustrated in FIG. 3. The substrate 5 is omitted in FIG. 3.

For example, a data area 7d that stores data may be provided in the memory layer 7; and a servo area 7s for controlling operations of the probe electrodes 9 may be provided in the memory layer 7 outside of the data area.

For example, the multiple first electrodes 8 may be provided corresponding to the data area 7d of the memory layer 7.

A probe array 9m is disposed to face the first electrodes 8 on the memory layer 7. The probe array 9m includes a probe substrate 9s and multiple probe electrodes 9 disposed in an array configuration on a major surface of the probe substrate 9s. Each of the multiple probe electrodes 9 includes, for example, a cantilever and is driven by multiplex drivers 9x and 9y.

Although it is possible to operate each of the multiple probe electrodes 9 individually using microactuators in the probe substrate 9s, all of the multiple probe electrodes 9 may have the same collective operation to access the data area 7d of the memory layer 7.

Using the multiplex drivers 9x and 9y, each of the probe electrodes 9 is moved, for example, in the X axis direction and the Y axis direction; and the positional information of the X axis direction and the Y axis direction is read from the servo area 7s of the memory layer 7. The positional information of the X axis direction and the Y axis direction is transferred to a driver 20.

The driver 20 can drive the XY scanner 4 based on the positional information to move the memory layer 7 in the X axis direction and the Y axis direction and positionally align the probe electrodes 9 and the first electrodes 8 of the memory layer 7.

For example, the probe electrodes 9 are moved to the desired position above the memory layer 7 in the state in which the probe electrodes 9 are raised away from the first electrodes 8. Subsequently, the probe electrodes 9 are lowered at the position of the desired first electrodes 8 and brought into contact with the first electrodes 8. Then, a voltage is applied to the multiple first electrodes 8 to perform the writing. Subsequently, the probe electrodes 9 are again moved to the location where the writing was performed to read or erase the written memory bit.

In other words, an electrical signal output by the drive unit 10 is applied to the first electrode 8 via the probe electrode 9 and the prescribed voltage is applied between the first electrode 8 and the second electrode 6 in the state in which the probe electrode 9 contacts the desired first electrode 8. Thereby, data can be written to, read from, and erased from the desired memory cell (memory bit).

Data can be written, for example, by applying a voltage higher than the second transition voltage V2 of the characteristics illustrated in FIG. 2 to the memory layer 7. Erasing can be performed by applying a voltage higher than the first transition voltage V1 and lower than the second transition voltage V2. To read, a voltage lower than the first transition voltage V1 is applied to read the resistance of the memory layer 7 as being the high resistance state HRS or the low resistance state LRS.

In the nonvolatile memory device 211 as well, the electric field E2 is applied or the current I2 flows between the first electrode of the first major surface 7a of the memory layer 7 and the second electrode 6 of the second major surface 7b. Thereby, the positional precision of the probe electrode can be mitigated to provide a probe nonvolatile memory device having reduced writing and reading defects.

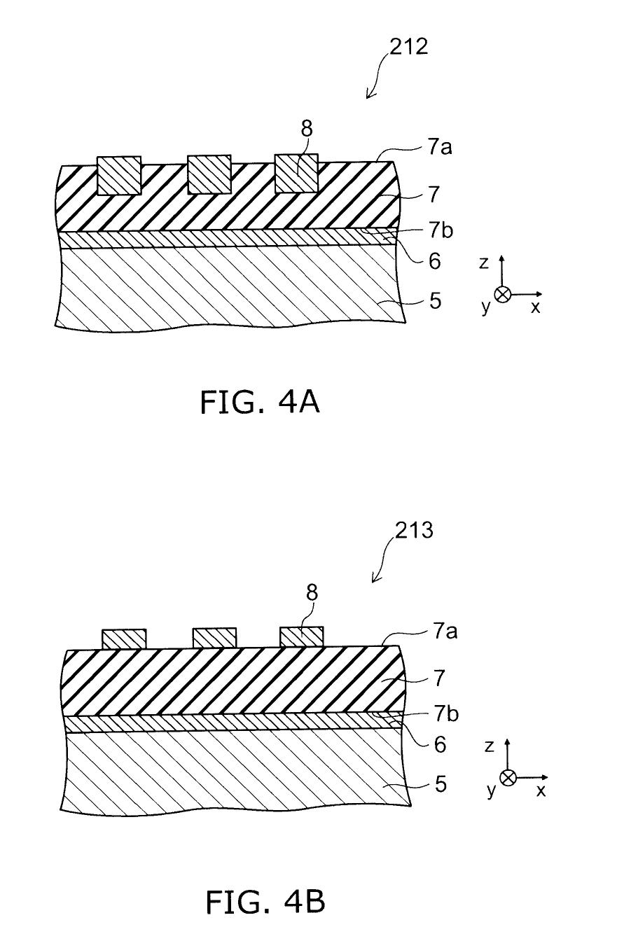

FIGS. 4A and 4B are schematic cross-sectional views illustrating the configurations of other nonvolatile memory devices according to an embodiment of the invention.

Namely, FIGS. 4A and 4B illustrate modifications of the configuration of the first electrode 8 of the nonvolatile memory device according to this embodiment and are cross-sectional views corresponding to the cross section along line A-A′ of FIG. 1A. The probe electrode 9 and the drive unit 10 are omitted in these drawings.

In a nonvolatile memory device 212 of the modification, the first electrode 8 protrudes from the memory layer 7 while a portion of the first electrode 8 is buried in the memory layer 7 as illustrated in FIG. 4A.

In a nonvolatile memory device 213 of another modification, the first electrode 8 is provided on the major surface 7a of the memory layer 7 without being buried in the memory layer 7 as illustrated in FIG. 4B. In such a case, the first electrode 8 protrudes from the memory layer 7.

By the first electrode 8 protruding from the memory layer 7 as in the nonvolatile memory devices 212 and 213, the contact between the first electrode 8 and the probe electrode 9 can be performed reliably even in the case of large fluctuations in the position of the probe electrode 9 in the Z axis direction.

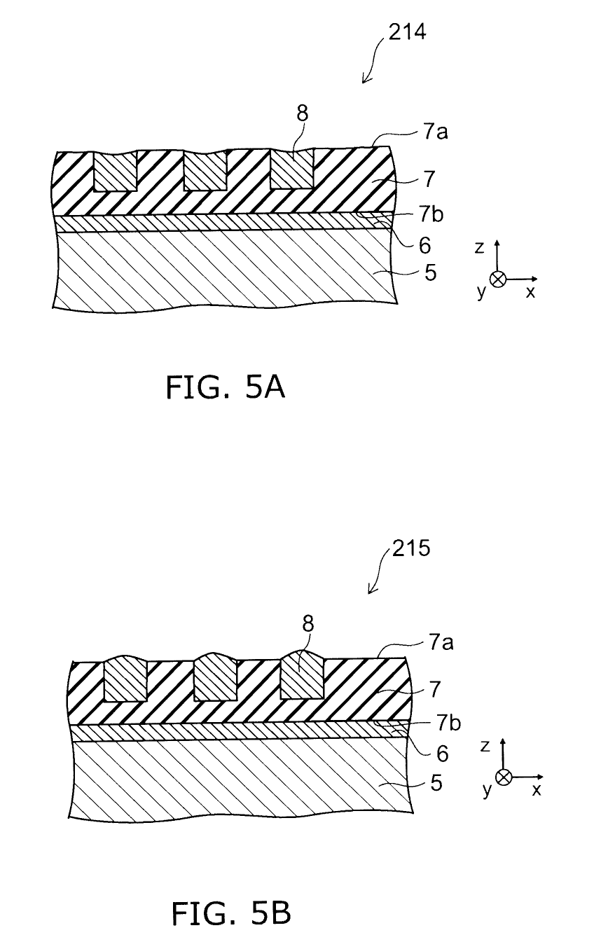

FIGS. 5A and 5B are schematic cross-sectional views illustrating the configuration of other nonvolatile memory devices according to an embodiment of the invention.

Namely, FIGS. 5A and 5B illustrate modifications of the configuration of the first electrode 8 of the nonvolatile memory device according to this embodiment and are cross-sectional views corresponding to the cross section along line A-A′ of FIG. 1A. The probe electrode 9 and the drive unit 10 are omitted in these drawings.

In a nonvolatile memory device 214 of a modification, the central portion of the upper face (the surface on the side facing the probe electrode 9) of each of the first electrodes 8 is recessed from the peripheral portion as illustrated in FIG. 5A. In other words, the central portion of the upper face of the first electrode 8 may have a sunken configuration. Thereby, it is easy to positionally align with the probe electrode 9; the contact surface area between the probe electrode 9 and the first electrode 8 can be enlarged; and the characteristics are more stable. As recited above, the configuration in which the central portion of the upper face of the first electrode 8 is sunken may be applied to all of the structures of the first electrode 8 described above.

In a nonvolatile memory device 215 of a modification, the upper face of the first electrode 8 has a rounded protruding configuration as illustrated in FIG. 5B. Thereby, damage of the first electrode 8 due to damage of corner portions of the upper face of the first electrode 8 by the contact between the probe electrode 9 and the first electrode 8 can be suppressed. Thus, it is particularly favorable to apply the structure in which the upper face of the first electrode 8 has a rounded protruding configuration to the nonvolatile memory devices 212 and 213 in which the first electrode 8 protrudes from the first major surface 7a.

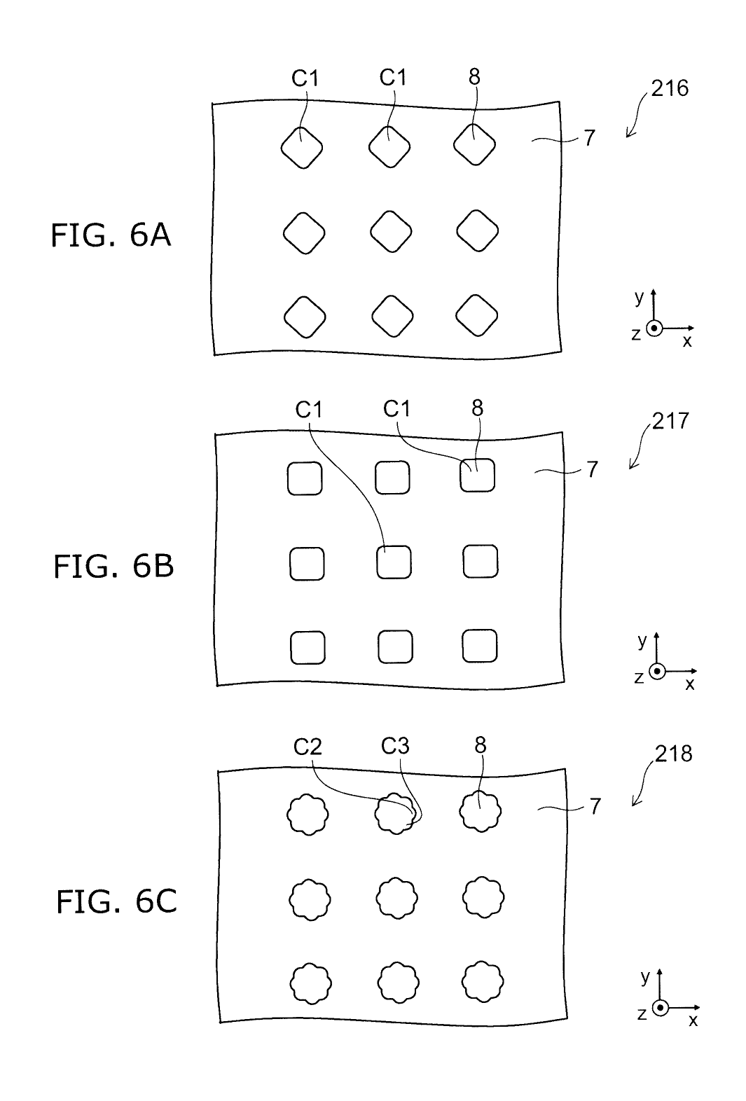

FIGS. 6A to 6C are schematic plan views illustrating the configurations of other nonvolatile memory devices according to an embodiment of the invention.

Namely, FIGS. 6A, 6B, and 6C illustrate various planar configurations of the first electrode 8 of the nonvolatile memory device according to this embodiment.

In a nonvolatile memory device 216 of a modification according to this embodiment, the planar configuration (the planar configuration as viewed from a direction perpendicular to the first major surface 7a) of the first electrode 8 is a square with rounded corners C1 as illustrated in FIG. 6A. The rounding of the corners C1 occurs when manufacturing the first electrode 8; and the configuration may be a square having corners C1 that are substantially not rounded. The diagonal lines of the squares are disposed along the X axis direction and the Y axis direction.

In a nonvolatile memory device 217 of another modification, the planar configuration of the first electrode 8 is a square having the (rounded) corners C1 as illustrated in FIG. 6B. In this case, the sides of the squares are disposed along the X axis direction and the Y axis direction.

In a nonvolatile memory device 218 of another modification, the planar configuration of the first electrode 8 has corners C2 provided in the X axis direction and the Y axis direction and corners C3 provided in directions diagonal with respect to the X axis direction and the Y axis direction as illustrated in FIG. 6C.

Thus, various modifications of the planar configuration of the first electrode 8 are possible.

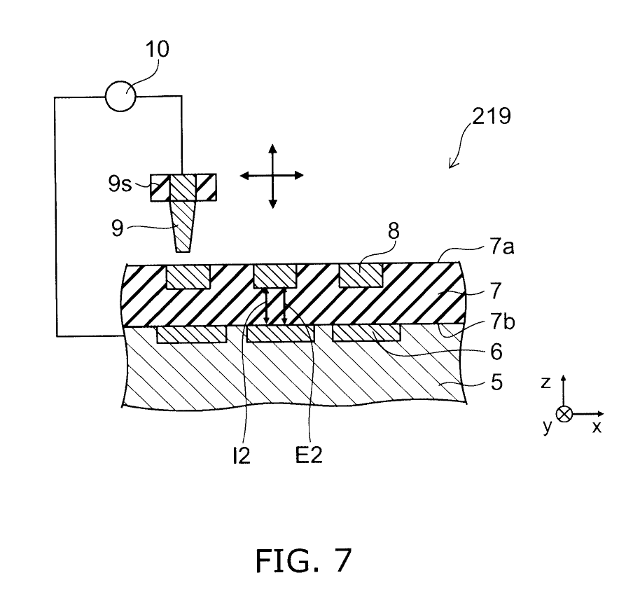

FIG. 7 is a schematic view illustrating the configuration of another nonvolatile memory device according to an embodiment of the invention.

Namely, FIG. 7 is a cross-sectional view corresponding to the cross section along line A-A′ of FIG. 1A.

In another nonvolatile memory device 219 according to this embodiment of the invention, the second electrode 6 is multiply provided as illustrated in FIG. 7. Otherwise, the nonvolatile memory device 219 may be similar to the nonvolatile memory device 210, and a description is omitted.

In this specific example, the second electrode 6 is divided along the X axis direction and multiply provided in band configurations aligned in the Y axis direction. Although the second electrode 6 in this specific example is buried in the substrate 5, the second electrode 6 may be buried in the memory layer 7 on the second major surface 7b side of the memory layer 7.

In other words, in the nonvolatile memory device 219, the second electrode 6 is multiply provided on the second major surface 7b; and the drive unit 10 performs at least one selected from applying the electric field E2 and providing the current I2 between at least one of the multiple first electrodes 8 and at least one of the multiple second electrodes 6 via the probe electrode 9.

In the nonvolatile memory device 219, for example, by multiply arranging the probe electrodes 9 in the X axis direction and providing the multiple second electrodes 6 in band configurations aligned in the Y axis direction, the selectivity with respect to each of the memory bits improves; the characteristics can be improved; and the memory density can be improved.

By the nonvolatile memory device 219 as well, the positional precision of the probe electrode can be mitigated to provide a probe nonvolatile memory device having reduced writing and reading defects.

Hereinabove, exemplary embodiments of the invention are described with reference to specific examples. However, the invention is not limited to these specific examples. For example, one skilled in the art may appropriately select specific configurations of components of nonvolatile memory devices such as substrates, memory layers, electrodes, probe electrodes, drive units, and the like from known art and similarly practice the invention. Such practice is included in the scope of the invention to the extent that similar effects thereto are obtained.

Further, any two or more components of the specific examples may be combined within the extent of technical feasibility; and are included in the scope of the invention to the extent that the purport of the invention is included.

Moreover, all nonvolatile memory devices practicable by an appropriate design modification by one skilled in the art based on the nonvolatile memory devices described above as exemplary embodiments of the invention also are within the scope of the invention to the extent that the purport of the invention is included.

Furthermore, various modifications and alterations within the spirit of the invention will be readily apparent to those skilled in the art. All such modifications and alterations should therefore be seen as within the scope of the invention.

1. A nonvolatile memory device, comprising:
a memory layer having a resistance changeable by performing at least one selected from applying an electric field and providing a current, the memory layer having a first major surface and a second major surface opposite to the first major surface;
a plurality of first electrodes provided on the first major surface;
a second electrode provided on the second major surface;
a probe electrode disposed to face the plurality of first electrodes, the probe electrode having a changeable relative positional relationship with the first electrodes; and
a drive unit connected to the probe electrode and the second electrode to record information in the memory layer by causing at least the one selected from the applying the electric field and the providing the current via the probe electrode to the memory layer between the second electrode and at least one of the plurality of first electrodes.

2. The device according to claim 1, wherein the probe electrode is movable in a plane parallel to the first major surface.

3. The device according to claim 1, wherein a surface area of the plurality of first electrodes in a plane parallel to the first major surface is larger than a surface area of a tip of the probe electrode on a side facing the first major surface.

4. The device according to claim 1, wherein at least one of the plurality of first electrodes is buried into the memory layer.

5. The device according to claim 1, wherein at least one of the plurality of first electrodes includes a surface having a central portion recessed from a peripheral portion on a side facing the probe electrodes.

6. The device according to claim 1, wherein at least one of the plurality of first electrodes includes a surface having a central portion protruding from a peripheral portion on a side facing the probe electrode.

7. The device according to claim 6, wherein at least one of the plurality of first electrodes includes a surface having a rounded protruding configuration on a side opposite to the second electrode.

8. The device according to claim 1, wherein the memory layer includes at least one selected from a resistance change material and a phase change material.

9. The device according to claim 1, wherein the memory layer includes at least one selected from the group consisting of NiOₓ, TiOₓ, CoOₓ, TaOₓ, MnOₓ, WOₓ, Al₂O₃, FeOₓ, HfOₓ, ZnMn₂O₄, ZnFe₂O₄, ZnCO₂O₄, ZnCr₂O₄, ZnAl₂O₄, CuCoO₂, CuAlO₂, NiWO₄, NiTiO₃, CoAl₂O₄, MnAl₂O₄, ZnNiTiO₄, PrₓCa₁₋ₓMnO₃ and SiC.

10. The device according to claim 9, wherein the memory layer further includes a dopant.

11. The device according to claim 1, wherein at least one selected from the plurality of first electrodes and the second electrode includes at least one selected from tungsten and platinum.

12. The device according to claim 1, wherein the probe electrode includes at least one selected from silicon, a carbon nanotube, and tungsten.

13. The device according to claim 1, wherein a surface of a tip of the probe electrode on a side facing the memory layer is covered with an electrically conductive thin film.

14. The device according to claim 1, wherein the probe electrode is multiply provided.

15. The device according to claim 1, wherein the plurality of first electrodes is arranged in a matrix configuration in a plane parallel to the first major surface.

16. The device according to claim 1, wherein the second electrode is multiply provided on the second major surface of the memory layer.

17. The device according to claim 16, wherein
each of the plurality of first electrodes is aligned in a band configuration along a first direction parallel to the first major surface, and
each of the plurality of second electrodes is aligned in a band configuration along a second direction perpendicular to the first direction and parallel to the first major surface.

18. The device according to claim 1, wherein each of the plurality of first electrodes has a circular or flattened circular planar configuration as viewed from a direction perpendicular to the first major surface.

19. The device according to claim 1, wherein each of the plurality of first electrodes has a planar configuration of a polygon with rounded corners as viewed from a direction perpendicular to the first major surface.

20. The device according to claim 1, wherein the probe electrode does not directly contact the memory layer.
